(19) United States
(12) Patent Application Publication
(10) Pub. No.: US 2023/0221080 A1
(43) Pub. Date: Jul. 13, 2023

(54) LIQUID VAPOR COMPOSITE HEAT DISSIPATION SYSTEM

(71) Applicant: Long Victory Instruments Co., Ltd., Taoyuan City (TW)

(72) Inventor: Chien-Chung Feng, Taoyuan City (TW)

(21) Appl. No.: 18/082,898

(22) Filed: Dec. 16, 2022

(30) Foreign Application Priority Data
Jan. 10, 2022 (TW) 111100994

(51) Int. Cl. F28D 15/04; F28D 15/02

(52) U.S. Cl. CPC F28D 15/043; F28D 15/046; F28D 15/0275

(57) ABSTRACT

A liquid-vapor composite heat dissipation system includes a heat exchange device filled with a working fluid, a number of liquid-vapor composite heat dissipation units that are positioned higher than the heat exchange device, each of the liquid-vapor composite heat sink units having a housing with an internal capillary occupying the interior of the housing and partially separating a spatially disconnected inlet chamber and an outlet chamber. The bottom of the housing is attached to a heat source. A liquid supply tube is connected to the heat exchange device at one end, and at the other end to a liquid inlet of each of the liquid-vapor composite heat sink units through each of the liquid supply pipes. A liquid return tube is connected to the heat exchange device at one end, and to each of the liquid-vapor composite heat sink units at the other end through each of the return pipes.

### FIELD OF THE DISCLOSURE

The present disclosure relates in general to a heat dissipation system, and more particularly, to a liquid-vapor composite heat dissipation system.

### BACKGROUND OF THE DISCLOSURE

A plate type heat exchanger is of a conventional heat dissipation technology. In one example, Taiwan Patent No. 1712771 discloses an inlet distributor for plate type heat exchanger, which uses two disconnected pipes and interposes a common metal wall therebetween as a partition wall. A hot liquid can flow through one pipe, while cold liquid can flow through the other pipe. Since the pipes are staggered, the hot and cold liquids can interact through the common metal wall and achieve the heat dissipation effect.

In another example, Taiwan Patent No. M504268, which is directed to a cooling device for multiple heat sources, uses a metal tube to transport liquid, and makes the metal tube pass through multiple heat sources in order to achieve the effect of heat dissipation for multiple heat sources.

In yet another example, Taiwan Patent No. M300866, which is directed to a multi-heat pipe heat dissipation structure for LED luminaires, uses multiple heat pipes to provide fast heat dissipation effect to one or more heat sources.

In the aforementioned technologies as referenced by Taiwan Patent No. 1712771 and Taiwan Patent No. 1712771, only liquids are used to exchange heat, and the effectiveness of the heat exchange is limited to heat conduction between liquids without using any heat pipe.

As to the Taiwan Patent No. M300866, heat pipes are used along with the technology of absorbing a large amount of heat energy by evaporating liquid into a vapor state. It is known that the heat dissipation effect is extremely limited when vapor chamber is used whereby a large amount of heat energy is absorbed by evaporating liquid into a vapor state. Additionally, the heat dissipation technology using heat pipes involves a closed liquid-vapor phase transition, noting that heat pipes have limited length and relatively high cost. If such is used in an environment where multiple servers are stacked on top of each other in a cabinet, multiple heat pipes are needed to address the length limitation that would lead to unfavorable cost increase, and therefore such usage is disfavored unless the application is directed to each server individually over any combining of the heat pipes into a system.

Another problem encountered in the conventional art is that heat dissipation for multiple heat sources is limited to the use of liquid-conducting heat exchange technology, or the use of heat pipes inside a small unit or a small device (e.g., a lamp), and therefore it is not feasible to provide the heat dissipation effect of using liquid vapor to absorb a large amount of heat energy for the cascading structure of multiple servers, particularly in a cabinet room environment.

### SUMMARY OF THE DISCLOSURE

It is therefore an object of the present disclosure to provide a liquid-vapor composite heat dissipation system which can effectively apply the heat dissipation effect of absorbing large amount of heat energy by evaporating liquid into a vapor state to the architecture of multiple heat sources, and can be applied to the architecture of the stacking layers of multiple servers in the cabinet room environment.

In order to achieve the above-mentioned object, the present disclosure proposes a liquid-vapor composite heat dissipation system that includes a heat exchange device having first and second channels that are adjacent and spaced apart, the first and second channels sharing at least one metal wall as part of the channel wall of the first and second channels, wherein the heat exchange device has a first inlet and a first outlet passing through the first and second channels, and a second inlet and a second outlet passing through the first and second channels, and wherein the first inlet is connected to a cooling water source, and the second channel is filled with a working fluid; and one or more liquid-vapor composite heat sink units positioned above the heat exchange device, each of the liquid-vapor composite heat sink units having a housing with a capillary that occupies the interior of the housing and partitions the interior of the housing into a spatially disconnected liquid inlet chamber and a steam outlet chamber, and the housing having a liquid inlet connected to the liquid inlet chamber, and an steam outlet connected to the steam outlet chamber, with the bottom of the housing being affixed to a heat source; a liquid supply tube, with one side of the liquid supply tube connected to the second outlet and the other side of the liquid supply tube connected to one or more liquid supply pipes, which are connected at one end to the liquid supply tube, and to the liquid inlet of each of the liquid-vapor composite heat sink units at the other end; and a pump which drives the working fluid in the liquid supply tube to flow towards each of the liquid supply pipes; and a liquid return tube extended downwardly and connected at a top side to each of the return pipes, and at the other side to end to outlet of each of the liquid-vapor composite heat sink units, and connected at a bottom side to the second inlet of the heat exchange device.

In this way, the present disclosure effectively utilizes the heat dissipation effect of liquid evaporating into vapor to absorb a large amount of heat energy, and applies such to the architecture of multiple heat sources. In addition, the present disclosure can be applied to the architecture of multiple servers stacked on top and bottom in the cabinet environment, solving the problems encountered in the conventional technology.

### BRIEF DESCRIPTION OF THE DRAWINGS

In order to illustrate the technical features of the present disclosure in detail, an exemplary embodiment is illustrated with drawings, wherein:

FIG. 1 is a schematic view of the liquid vapor composite cooling system according to the first exemplary embodiment of the present disclosure;

FIG. 2 is a schematic view of the heat exchange device in the liquid vapor composite cooling system according to the first exemplary embodiment of the present disclosure;

FIG. 3 is an exploded view of FIG. 2 according to the first exemplary embodiment of the present disclosure;

FIG. 4 is a schematic cross-sectional view of the heat exchange device according to the first exemplary embodiment of the present disclosure; and

FIG. 5 is a schematic view of the liquid vapor composite cooling system according to the second exemplary embodiment of the present disclosure.

### DETAILED DESCRIPTION OF THE EXEMPLARY EMBODIMENTS

In order to illustrate the technical features of the present disclosure in detail, the following exemplary embodiments are cited and illustrated with accompanying drawings, among others.

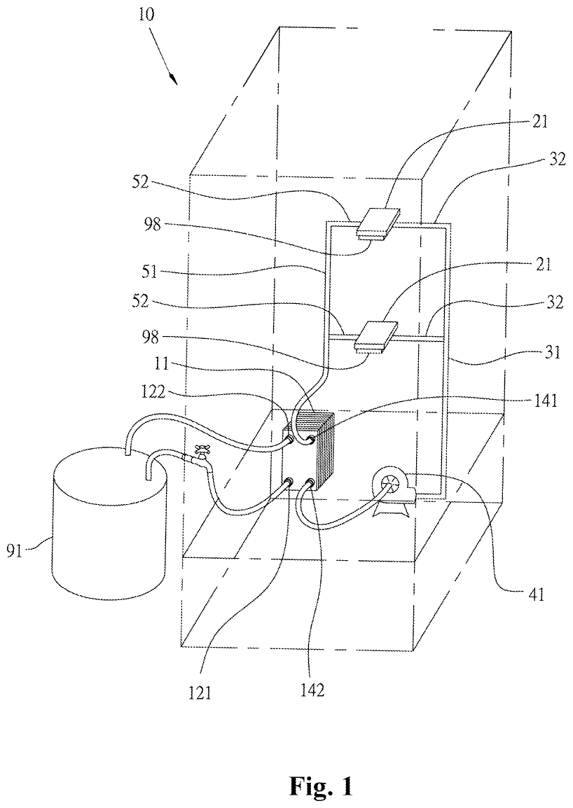

As shown in FIGS. 1 to 4, a first exemplary embodiment in the present disclosure includes a liquid-vapor composite heat dissipation system 10, consisting mainly of a heat exchange device 11, a pair of liquid-vapor composite heat dissipation units 21, a liquid supply tube 31, a pump 41, and a liquid return tube 51.

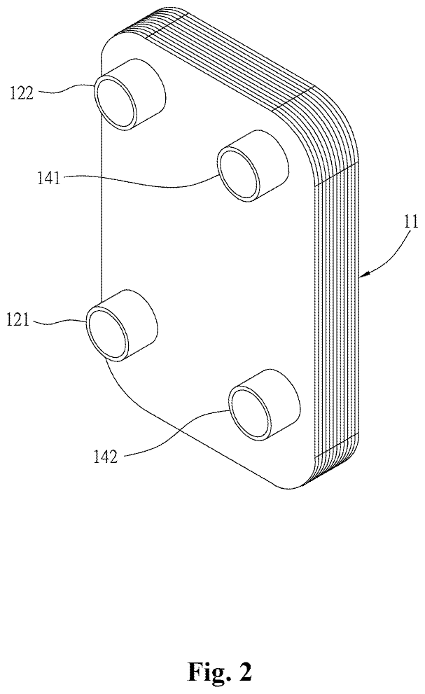

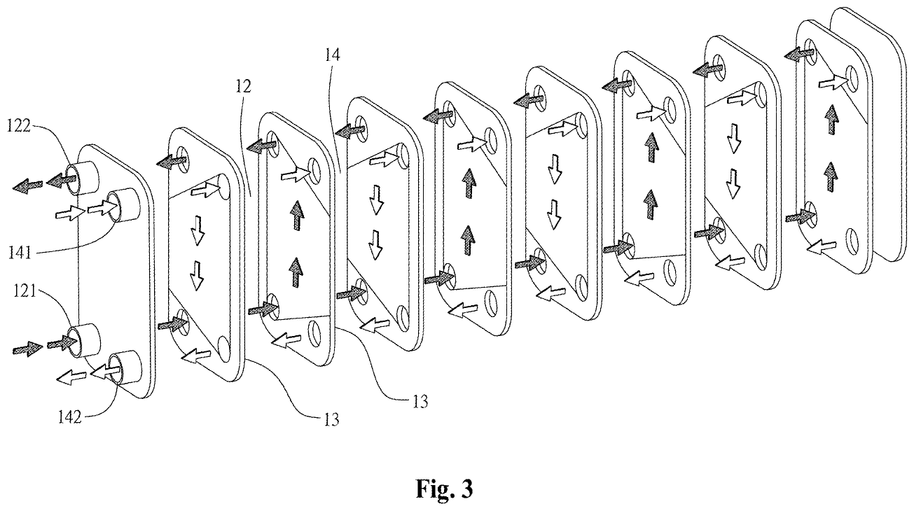

As shown in FIGS. 2 and 3, the heat exchange device 11 is exemplarily consisted of a plate heat exchanger which has a first channel 12 and a second channel 14 that are spaced apart. The first channel 12 and the second channel 14 are partly adjacent to each other and share metal walls 13 as part of the channel walls of the first channel 12 and the second channel 14. The heat exchange device 11 also has a first inlet 121 and a first outlet 122 connected to the first channel 12, and a second inlet 141 and a second outlet 142 connected to the second channel 14. The first inlet 121 is connected to a cooling water source 91, and the second channel 14 is filled with a working fluid 92. Since the plate heat exchanger is a known technology, the detailed structure of the plate heat exchanger will not be elaborated. In addition, the heat exchange device 11 as shown in FIGS. 2 and 3 is for the convenience of presentation and not drawn to actual scale.

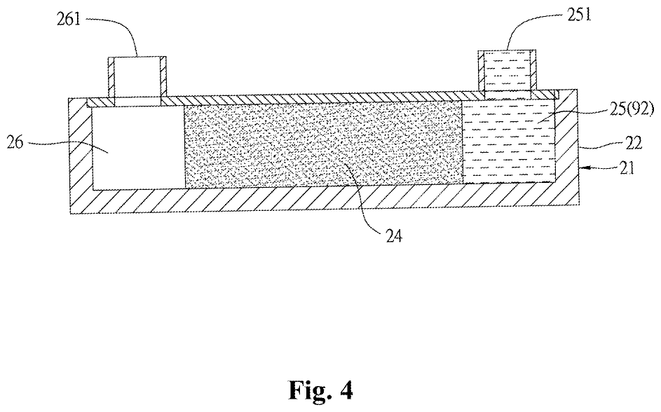

The pair of liquid-vapor composite heat dissipation units 21 is placed at a position that is higher than the heat exchange device 11. As shown in FIG. 4, each of the liquid-vapor composite heat dissipation units 21 has a housing 22, with a capillary 24 arranged inside the housing 22. In the first exemplary embodiment, the capillary 24 is of a copper powder sintered structure that occupies the interior of the housing 22 and divides the interior of the housing 22 into a spatially disconnected liquid inlet chamber 25 and a steam outlet chamber 26, and the housing 22 has a liquid inlet 251 that communicates with the liquid inlet chamber 25. The housing 22 has a liquid inlet 251 connected to the liquid inlet chamber 25. The housing 22 also has a steam outlet 261 connected to the steam outlet chamber 26. The bottom of the housing 22 can be used to attach one of the heat sources 98. Each of the heat sources 98 can come from servers stacked above and below each other, and in such instance, each heat-generating chip from each server, such as a central processing unit (CPU), serves as one of the heat sources 98 that is affixed to the bottom of the housing 22 in one of the liquid-vapor composite heat dissipation units 21. In FIG. 1, each of the heat sources 98 is merely illustrated by a block, and the physical structure of the server or cabinet is not shown. Each of the liquid-vapor composite heat dissipation units 21 as shown in FIG. 4 is only for illustrative purpose and not drawn to the actual scale.

The liquid supply tube 31 has one end connected to the second outlet 142, and the other end is closed at the top and is located at the higher one of the liquid-vapor composite heat dissipation units 21. The liquid supply pipe 31 contains the working liquid 92, and the body of the liquid supply pipe 31 is connected to a pair of liquid supply pipes 32. Each of the liquid supply pipes 32 is connected to the liquid supply tube 31 at one end, and the other end is respectively connected to the liquid inlet 251 of each of the liquid-vapor composite heat dissipation units 21.

The pump 41 drives the working fluid 92 to flow from the liquid supply tube 31 to each of the liquid supply sub pipes 32.

A liquid return tube 51 is connected to one end of a pair of return pipes 52, and the steam outlet 261 of the liquid-vapor composite heat sink unit 21 is connected to the other end of the pair of return pipes 52. The liquid return tube 51 is further connected to the second inlet 141 of the heat exchange device 11 toward the bottom end of the liquid return tube 51.

In this first exemplary embodiment, the second inlet 141 is positioned higher than the second outlet 142, forming a spatial relationship that is sufficient to have a water level difference, which helps the liquid to flow naturally from the second inlet 141 to the second outlet 142 due to gravity. In this first exemplary embodiment, the liquid supply tube 31 is a pipeline extending from the bottom to the top, and the liquid return tube 51 is another pipeline extending from the top to the bottom. In practice, both the liquid supply tube 31 and the liquid return tube 51 can be set as up and down straight pipelines.

The structure of the first exemplary embodiment has been described above, and operating state of the first exemplary embodiment will be described henceforth.

As shown in FIG. 1, before use, each of the liquid-vapor composite heat sink units 21 is installed on each of the heat-generating chips of the server, i.e., each of the heat sources 98, and each of the liquid-vapor composite heat sink units 21 is connected to each of the liquid supply pipes 32 and each of the return pipes 52. The cooling water source 91 provides cold water that enters the first inlet 121, exits the first outlet 122, and returns to the cooling water source 91 for cooling. In another arrangement, the cooling water source 91 can be connected in a way that does not use the recycling process, such as providing the cold water only to the first outlet 122 and directing the water flowing out of the first outlet 122 for use in another way.

In use, the cooling water source 91 is controlled to provide cold water, and the pump 41 is controlled to drive the working fluid 92 to rise from the liquid supply tube 31 at a low flow rate, and flow into through each of the liquid supply pipes 32. The liquid inlet chamber 25 of each liquid vapor composite heat sink units 21 is adsorbed by the capillary 24 of each liquid vapor composite heat sink units 21. Since the pump 41 is controlled to be driven at a low flow rate, the working liquid 92 adsorbed by the capillary 24 is not promptly pushed out of the capillary 24 of each liquid-vapor composite heat dissipation units 21 in order to enter the steam outlet chamber 26 in a liquid state. When each of the servers is turned on, the heat-generating chip in the from each of the heat source 98s will operate and generate heat, and the generated heat will heat the working fluid 92 in each of the liquid-vapor composite heat sink units 21, and the heat energy emitted will heat the working fluid 92 in each of the liquid-vapor composite heat sink units 21. The adsorbed working liquid 92 in each capillary 24 will evaporate into a vapor state and enter the associated steam outlet chamber 26, and then return to the liquid return tube 51 by passing through each of the return pipes 52. In this process, some of the working fluid 92 in vapor form will be cooled by contacting the walls of each of the return pipes 52 and liquid return tube 51, causing the working fluid 92 in liquid form to be condensed, while the working fluid 92 not yet condensed will enter the second channel 14 of the heat exchange device 11 through the liquid return tube 51. By having the cold water flowing in the first channel 12, the working fluid 92 can be cooled by the common walls 13, and the working fluid 92 in the second channel 14 is condensed into a liquid state, and finally flows through the second outlet 142 to the pump 41 to be driven again. The low flow rate referred to in the present disclosure generally refers to the speed of liquid supply that is similar to the speed of vaporization of the working fluid 92 into a vapor working fluid, so it is a low flow rate driving method as compared to conventional pumps.

In addition, the liquid-vapor composite heat sink units 21 are placed at a higher position than the heat exchange device 11, thereby assisting the working fluid 92 in each of the return pipes 52 and the liquid return tube 51 to flow in the direction of the heat exchange device 11 using gravity.

If the flow rate of the pump 41 is properly controlled, the working fluid 92 can enter the liquid-vapor composite heat sink units 21 at a rate equal to the vaporization rate and maintain a stable operating condition, thus providing excellent heat dissipation from multiple heat sources.

As can be seen from the above, the present disclosure can effectively evaporate liquid into a vapor state to absorb a large amount of heat energy, and apply the heat dissipation effect to the structure of multiple heat sources, and also provide the effect of heat exchange with working fluid 92 by the cooling water source 91. The composite architecture that combines the technologies in liquid-vapor phase conversion and water cooling, when applied to the structure of multiple servers stacked on top and bottom in the cabinet environment, solves the problems encountered by the conventional technology.

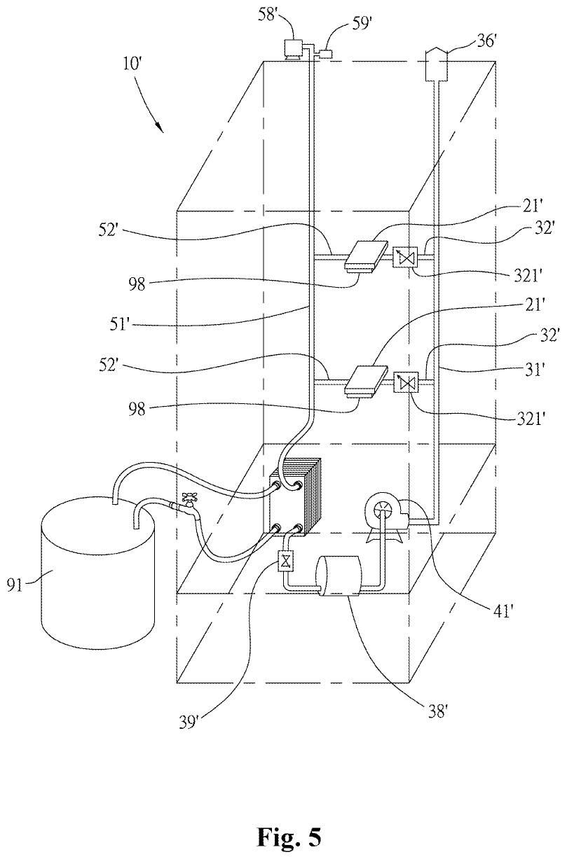

A second exemplary embodiment of the present disclosure is shown in FIG. 5, which includes a liquid-vapor composite cooling system 10′ that is mainly the same as the first embodiment, but differs in the following aspects.

Since at times the non-condensing gas can exist in a liquid supply tube 31′, and in order to facilitate the release of the non-condensing gas in the liquid supply tube 31′, a release valve 36′ is set up at the top of the liquid supply tube 31′ according to the second exemplary embodiment so that the non-condensable gas in the liquid supply tube 31′ can be released. Still, the use the release valve 36′ is optional since the non-condensing gas in the liquid supply tube 31′ can be processed without the using the release valve 36′. Additionally, each of liquid supply pipes 32′ can have a check valve 321′ for preventing the working liquid 92 from flowing back to the liquid supply tube 31′. Each of the check valves 321′ can be optionally positioned at the liquid supply tube 31′ instead of positioned at each of the liquid supply pipes 32′. Still, the use of the check valves 321′ is optional since the driving speed of the pump 41′ can be controlled to achieve the effect of preventing the backflow of the working fluid 92.

To conveniently drive the working fluid 92, the second exemplary embodiment provides a liquid storage tank 38′ which is connected to the liquid supply tube 31′. Such arrangement allows the working fluid 92 to flow first from the second outlet 142′ to the liquid supply tube 31′, then to the liquid storage tank 38′, and then driving by a pump 41′ towards a pair of liquid supply pipes 32′. The liquid storage tank 38′ is provided so that the working fluid 92 can be stored in the liquid storage tank 38′ first, and then the liquid storage tank 38′ can play a role in regulating the flow rate of the working fluid 92 so as to provide a buffering effect when the return flow rate of the working fluid 92 is different from that of the supply rate, thereby taking the advantage that each of the working fluid 92 can be regulated to provide a buffering effect. At times when the heating power of each heat source 98 is different, the evaporation rate of the working fluid 92 in each of the liquid-vapor composite heat sink units 21′ will be different, meaning that the rate of condensation and return of the working fluid 92 will be different from that of the liquid supply rate.

The second exemplary embodiment further provides a hydrophobic valve 39′, located in the liquid supply tube 31′, and more specifically between the second outlet (see FIG. 2) and the liquid storage tank 38′. The hydrophobic valve 39′ only allows the liquid to pass through, and does not allow the non-condensable gas or vapor working fluid 92 to pass through, so as to ensure that the working fluid 92 entering the liquid reservoir 38′ is in a liquid form.

Additionally, the second exemplary embodiment provides a vacuum pump 58′ and a vacuum valve 59′, which are located in the return pipe 51′ and specifically at the top of the return pipe 51′.

In the second exemplary embodiment, details of the cabinet architecture for multiple servers are provided. In the multi-server architecture, the servers can be hot-swapped for maintenance. Therefore, the practical application of the present disclosure allows for a number of liquid and gas plugs (not shown in the figure) to be setup in each of the servers, and set up a number of liquid and gas sockets in the cabinet to be connected to each of the liquid supply pipes 32′ and each of the return pipes 52′. Thus, when the servers are hot-plugged, the installation or removal can be completed directly through the plug-in or plug-out relationship of the plugs to the sockets. Such a hot-plugging process may cause a non-condensable gas (such as nitrogen) to enter the liquid supply tube 31′. Therefore, the release valve 36′ can be used to release the non-condensable gas. If the non-condensable gas flows into the return pipe 51′ through the capillary material (refer to FIG. 4) of each of the liquid-vapor composite heat dissipation units 21′, the vacuum pump 58′ and vacuum valve 59′ can be used to evacuate the return pipe 51′, so that not only there is no non-condensable gas in the return pipe 51′, but also a sufficient negative pressure can be formed so that the working liquid 92 can be vaporized into a vapor state at a lower temperature.

The rest of the structures, working states, and effects achieved in the second exemplary embodiment are generally the same as those in the first exemplary embodiment, and will not be repeated here.

The present disclosure has been described with reference to the exemplary embodiments, and such description is not meant to be construed in a limiting sense. It should be understood that the scope of the present disclosure is not limited to the above-mentioned embodiment, but is limited by the accompanying claims. It is, therefore, contemplated that the appended claims will cover all modifications that fall within the true scope of the present disclosure. Without departing from the object and spirit of the present disclosure, various modifications to the embodiments are possible, but they remain within the scope of the present disclosure, will be apparent to persons skilled in the art.

What is claimed is:

1. A liquid-vapor composite heat dissipation system, comprising:
a heat exchange device having first and second channels that are adjacent and spaced apart, the first and second channels sharing at least one metal wall as part of the channel wall of the first and second channels, wherein the heat exchange device has a first inlet and a first outlet passing through the first and second channels, and a second inlet and a second outlet passing through the first and second channels, and wherein the first inlet is connected to a cooling water source, and the second channel is filled with a working fluid; and
one or more liquid-vapor composite heat sink units positioned above the heat exchange device, each of the liquid-vapor composite heat sink units having a housing with a capillary that occupies the interior of the housing and partitions the interior of the housing into a spatially disconnected liquid inlet chamber and a steam outlet chamber, and the housing having a liquid inlet connected to the liquid inlet chamber, and an steam outlet connected to the steam outlet chamber, with the bottom of the housing being affixed to a heat source;
a liquid supply tube, with one side of the liquid supply tube connected to the second outlet and the other side of the liquid supply tube connected to one or more liquid supply pipes, which are connected at one end to the liquid supply tube, and to the liquid inlet of each of the liquid-vapor composite heat sink units at the other end; and
a pump which drives the working fluid in the liquid supply tube to flow towards each of the liquid supply pipes; and
a liquid return tube extended downwardly and connected at a top side to each of the return pipes, and at the other side to end to outlet of each of the liquid-vapor composite heat sink units, and connected at a bottom side to the second inlet of the heat exchange device.

2. The liquid-vapor composite cooling system according to claim 1, wherein the second inlet is placed at a higher position than the second outlet.

3. The liquid-vapor composite heat dissipation system according to claim 1, wherein the liquid supply tube is a first pipeline extending from the bottom to the top, and the return pipe is a second pipeline pipe extending from the top to the bottom.

4. The liquid-vapor composite heat dissipation system according to claim 1, wherein a top end of the liquid supply tube is equipped with a release valve.

5. The liquid-vapor composite heat dissipation system according to claim 1, further comprising a liquid storage tank connected to the liquid supply tube, wherein the working fluid flowing from the second outlet enters the liquid storage tank through the liquid supply tube first before driven by the pump and subsequently flowing into the liquid supply pipes.

6. The liquid-vapor composite heat dissipation system according to claim 1, wherein the liquid supply tube or each of the liquid supply pipes is provided with a check valve to prevent the working fluid from flowing backwards.

7. The liquid-vapor composite heat dissipation system according to claim 1, wherein a vacuum pump and a vacuum valve are provided in the liquid return tube, and positioned at a top end of the liquid return tube.

8. The liquid-vapor composite heat dissipation system according to claim 1, further comprising a hydrophobic valve located in the liquid supply pipe, wherein the hydrophobic valve allows the working fluid not in the form of non-condensing gas or vapor to pass through.

9. The liquid-vapor composite heat dissipation system according to claim 1, wherein the capillary is of a copper powder sintered structure, nickel powder sintered structure, or Teflon material structure.
